(19) United States
(12) Patent Application Publication
(10) Pub. No.: US 2026/0060058 A1
(43) Pub. Date: Feb. 26, 2026

(54) SEMICONDUCTOR PACKAGE

(71) Applicant: Samsung Electronics Co., Ltd., Suwon-si (KR)

(72) Inventors: Eunmi KIM, Suwon-si (KR); Byungkyu KIM, Suwon-si (KR); Jaewha PARK, Suwon-si (KR); Sujeong PARK, Suwon-si (KR); Jaeyoung CHOI, Suwon-si (KR)

(73) Assignee: Samsung Electronics Co., Ltd., Suwon-si (KR)

(21) Appl. No.: 19/089,295

(22) Filed: Mar. 25, 2025

(30) Foreign Application Priority Data
Aug. 26, 2024 (KR) 10-2024-0114490

(51) Int. Cl. H01L 23/00; H01L 23/31; H01L 23/48; H01L 25/07

(52) U.S. Cl. CPC H01L 24/06; H01L 23/481; H01L 24/08; H01L 25/074; H01L 23/3107; H01L 2224/0603; H01L 2224/06181; H01L 2224/08145; H01L 2225/06541

(57) ABSTRACT

A semiconductor package is provided. The semiconductor package includes a first semiconductor chip including a device region and a dummy region surrounding the device region in a two-dimensional perspective, second semiconductor chips on an upper surface of the device region of the first semiconductor chip, and a molding layer on the first semiconductor chip and covering the second semiconductor chips, wherein each of the second semiconductor chips includes a second semiconductor substrate, a second lower pad on a lower surface of the second semiconductor substrate, and a second upper pad in an upper portion of the second semiconductor substrate, and a volume of the second lower pad is greater than a volume of the second upper pad.

### CROSS-REFERENCE TO RELATED APPLICATION

This application is based on and claims priority under 35 U.S.C. § 119 to Korean Patent Application No. 10-2024-0114490, filed on Aug. 26, 2024, in the Korean Intellectual Property Office, the disclosure of which is incorporated by reference herein in its entirety.

### BACKGROUND

The present disclosure relates to semiconductor packages, and more particularly, to semiconductor packages including stacked semiconductor chips.

Semiconductor packages have been implemented in a type of an integrated circuit chip to be suitably used in electronic products. Generally, in semiconductor packages, a semiconductor chip is mounted on a printed circuit board and is electrically connected to the printed circuit board by using a bonding wire or a bump. As the electronics industry advances, semiconductor packages may need to implement a higher-capacity characteristic. Also, as electronic products are miniaturized, the demand for miniaturization of semiconductor packages is increasing.

### SUMMARY

Some example embodiments of the inventive concepts provide semiconductor packages having enhanced reliability.

Some example embodiments of the inventive concepts provide methods of manufacturing a semiconductor package at an enhanced yield rate and/or semiconductor packages manufactured by the method.

According to an example embodiment of the inventive concepts, a semiconductor package includes a first semiconductor chip including a device region and a dummy region surrounding the device region in a two-dimensional perspective, second semiconductor chips on an upper surface of the device region of the first semiconductor chip, and a molding layer on the first semiconductor chip, the molding layer covering the second semiconductor chips, wherein each of the second semiconductor chips includes a second semiconductor substrate, a second lower pad on a lower surface of the second semiconductor substrate, and a second upper pad on an upper surface of the second semiconductor substrate, and a volume of the second lower pad is greater than a volume of the second upper pad.

According to an example embodiment of the inventive concepts, a semiconductor package includes a first semiconductor chip, second semiconductor chips on an upper surface of the first semiconductor chip, and a molding layer on the first semiconductor chip, the molding layer covering the second semiconductor chips, wherein the first semiconductor chip includes a first semiconductor substrate, a first upper insulation layer on an upper surface of the first semiconductor substrate, the first upper insulation layer including a first insulation layer and a second insulation layer, a first upper pad in the second insulation layer, and a first lower pad on a lower surface of the first semiconductor substrate, each of the second semiconductor chips includes a second semiconductor substrate, a second upper insulation layer on an upper surface of the second semiconductor substrate, a second lower insulation layer on a lower surface of the second semiconductor substrate, a second upper pad in the second upper insulation layer, and a second lower pad in the second lower insulation layer, a volume of the first lower pad is greater than a volume of the first upper pad, and a volume of the second lower pad is greater than a volume of the second upper pad.

According to an example embodiment of the inventive concepts, a semiconductor package includes a first semiconductor chip including a first semiconductor substrate, a first upper insulation layer on an upper surface of the first semiconductor substrate, the first upper insulation layer including a first insulation layer and a second insulation layer, a first through silicon via passing through the first semiconductor substrate, a first wiring pattern in the first insulation layer, the first wiring pattern electrically connected to the first through silicon via, a first upper pad in the second insulation layer, the first upper pad electrically connected to the first wiring pattern, and a first lower pad on a lower surface of the first semiconductor substrate, second semiconductor chips on an upper surface of the first semiconductor chip, each of the second semiconductor chips including a second semiconductor substrate, a second upper insulation layer on an upper surface of the second semiconductor substrate, a second lower insulation layer on a lower surface of the second semiconductor substrate, a second upper pad in the second upper insulation layer, and a second lower pad in the second lower insulation layer, a molding layer on the first semiconductor chip, the molding layer covering sidewalls of the second semiconductor chips, and a lower bump on a lower surface of the first semiconductor chip, the lower bump electrically connected to the first lower pad, wherein a thickness of the second lower pad in a vertical direction is greater than a thickness of the second upper pad in the vertical direction, a length of the second lower pad in a first horizontal direction and a length of the second lower pad in a second horizontal direction perpendicular to the first horizontal direction are greater than each of a length of the second upper pad in the first horizontal direction and a length of the second upper pad in the second horizontal direction, and when viewed from above, an area of the second lower pad is two times an area of the second upper pad, and an area where the second upper pad overlaps the second lower pad is half of an area of the second lower pad.

### BRIEF DESCRIPTION OF THE DRAWINGS

Example embodiments will be more clearly understood from the following detailed description taken in conjunction with the accompanying drawings in which:

FIG. 1 is a plan view illustrating a semiconductor package according to an example embodiment;

FIG. 2 is a cross-sectional view taken along line I-I′ of FIG. 1, according to an example embodiment;

FIG. 3 is a cross-sectional view taken along line I-I′ of FIG. 1, according to another example embodiment;

FIG. 4 is a cross-sectional view taken along line I-I′ of FIG. 1, according to another example embodiment;

FIG. 5 is an enlarged view of a region II of FIG. 2, according to an example embodiment;

FIG. 6 is an enlarged view of the region II of FIG. 2, according to another example embodiment;

FIG. 7 is a plan view illustrating a second upper pad and a second lower pad each included in a semiconductor package according to an example embodiment;

FIG. 8 is an enlarged view of a region III of FIG. 2, according to an example embodiment;

FIG. 9 is a graph showing a warpage skew improvement rate of a semiconductor chip with respect to a lower pad volume depending on each case;

FIGS. 10 to 13 are diagrams for describing a manufacturing process of a semiconductor package according to an example embodiment; and

FIG. 14 is a cross-sectional view illustrating a semiconductor package according to an example embodiment.

### DETAILED DESCRIPTION

Example embodiments may be variously modified and may have various forms, and thus, some example embodiments may be illustrated in the drawings and will be described in detail. However, this are not intended to limit example embodiments to a specific form. Also, the example embodiments described below may be merely examples, and various modifications may be made from the example embodiments.

All example embodiments or the terms used herein are for explaining the inventive concepts in detail, and unless defined by the claims, the scope of the inventive concepts is not limited by the disclosed example embodiments or the terms.

Herein, unless specially described, a vertical direction may be defined as a Z direction, and each of a first horizontal direction and a second horizontal direction may be defined as a horizontal direction perpendicular to the Z direction. The first horizontal direction may be referred to as an X direction, and the second horizontal direction may be referred to as a Y direction. A vertical level may be referred to as a height level based on the vertical direction (the Z direction). A horizontal width in the first horizontal direction may be referred to as a length in the horizontal direction (the X direction and/or the Y direction), and a vertical length may be referred to as a length in the vertical direction (the Z direction).

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

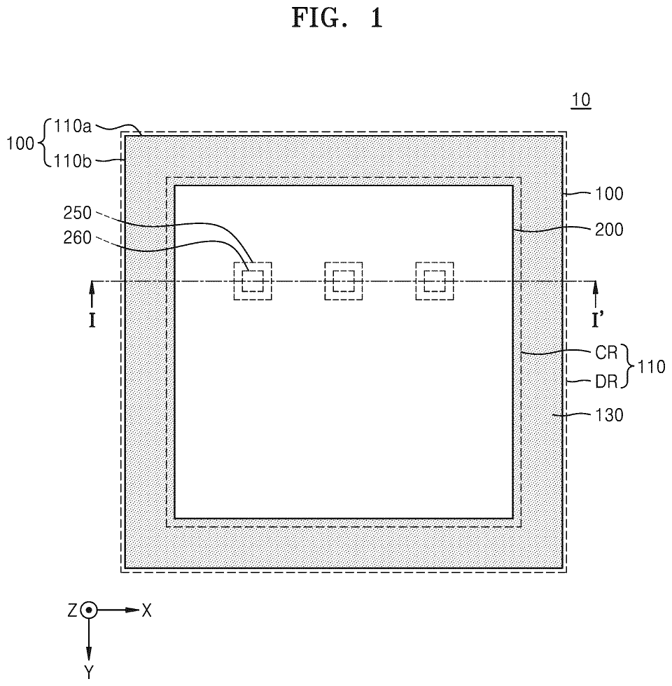

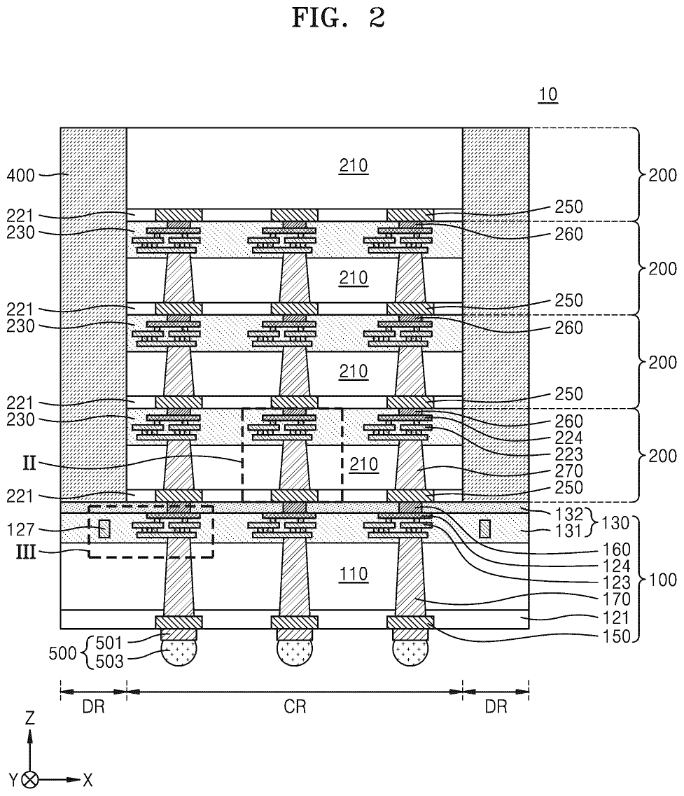

FIG. 1 is a plan view illustrating a semiconductor package 10 according to an example embodiment. FIG. 2 is a cross-sectional view taken along line I-I′ of FIG. 1, according to an example embodiment.

Referring to FIGS. 1 and 2, the semiconductor package 10 may include a memory package such as a high bandwidth memory (HBM) package. The semiconductor package 10 may be a chip stack package. The semiconductor package 10 may include a first semiconductor chip 100, second semiconductor chips 200, a molding layer 400, and a lower bump 500.

The first semiconductor chip 100 may be a lower semiconductor chip. The first semiconductor chip 100 may be a logic chip or a buffer chip. The first semiconductor chip 100 may include a first semiconductor substrate 110, a first lower pad 150, a first lower insulation layer 121, a first wiring pattern 123, a first through silicon via 170, a first upper insulation layer 130, and a first upper pad 160. A first horizontal direction (an X direction) may be parallel to a lower surface of the first semiconductor substrate 110. A second horizontal direction (a Y direction) may intersect with the lower surface of the first semiconductor substrate 110. The second horizontal direction (the Y direction) may be parallel to the lower surface of the first semiconductor substrate 110 and may intersect with the first horizontal direction (the X direction). For example, the second horizontal direction (the Y direction) may be perpendicular to the first horizontal direction (the X direction). For example, a third direction (a Z direction) may be perpendicular to the lower surface of the first semiconductor substrate 110. The third direction (the Z direction) may be a vertical direction.

A thickness of the first semiconductor chip 100 may be about 30 μm to about 80 μm. A thickness of the first semiconductor chip 100 is about 80 μm or less, and thus, the semiconductor package 10 may be miniaturized. A thickness of the first semiconductor chip 100 is about 30 μm or more, and thus, the damage of the first semiconductor chip 100 may be reduced or prevented in a manufacturing process of the semiconductor package 10. A thickness T of the first semiconductor chip 100 may correspond to an interval between the lower surface and an upper surface of the first semiconductor chip 100.

A plurality of second semiconductor chips 200 may be provided on the first semiconductor chip 100. The second semiconductor chips 200 may be vertically stacked on the upper surface of the first semiconductor chip 100. Herein, unless separately limited, “vertical” may denote being parallel to the vertical direction (the Z direction). The second semiconductor chips 200 may be upper semiconductor chips. The second semiconductor chip chips 200 may be the same semiconductor chips. Each of the second semiconductor chips 200 may be a memory chip such as a dynamic random access memory (RAM) (DRAM) chip. For examples, each of the second semiconductor chips 200 may be an HBM chip. Storage capacities of the second semiconductor chips 200 may be equal to one another. The second semiconductor chips 200 may have the same size. For example, the second semiconductor chips 200 may have the same or substantially similar width. Sidewalls of the second semiconductor chips 200 may be vertically aligned with one another. On the other hand, a thickness of an uppermost second semiconductor chip 200 may be greater than that of each of the other second semiconductor chips 200. Thicknesses of the other second semiconductor chips 200 may be substantially equal to one another. A width of an arbitrary element may be measured in the first horizontal direction (the X direction). A width of an arbitrary element may be measured in the vertical direction (the Z direction). Widths, thicknesses, sizes, and levels of arbitrary elements being equal to one another may denote the sameness of an error range occurring in a process. The second semiconductor chips 200 may be semiconductor chips which differ from the kind of first semiconductor chip 100. A width of the first semiconductor chip 100 may be greater than widths of the second semiconductor chips 200.

The number of second semiconductor chips 200 may not be limited to the illustration of FIG. 2 and may be variously modified. For example, the semiconductor package 10 may include a single of second semiconductor chip 200 or four or more second semiconductor chips 200. For example, the semiconductor package 10 may include eight second semiconductor chips 200, twelve second semiconductor chips 200, or sixteen second semiconductor chips 200.

Hereinafter, elements of the first semiconductor chip 100 will be described.

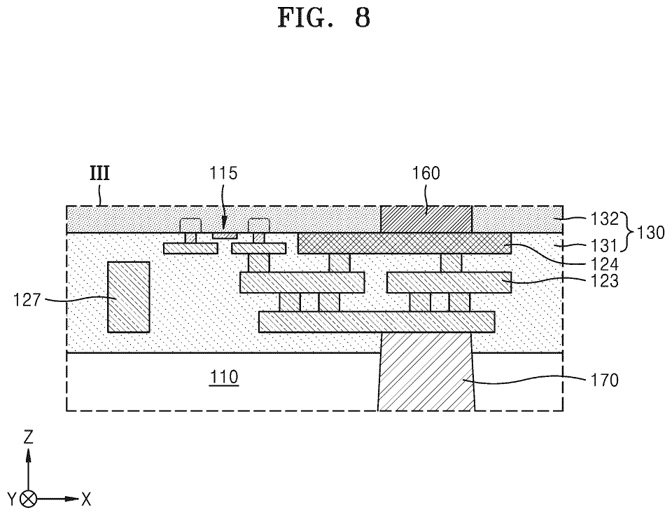

The first semiconductor substrate 110 may be a first substrate. In a two-dimensional perspective, the first semiconductor substrate 110 may include a chip region CR and a dummy region DR. The chip region CR may correspond to a device region. The chip region CR of the first semiconductor substrate 110 may be a center region (or a central region) of the first semiconductor substrate 110. The dummy region DR of the first semiconductor substrate 110 may be an edge region of the first semiconductor substrate 110. In a two-dimensional perspective, the dummy region DR of the first semiconductor substrate 110 may surround the chip region CR. For example, the dummy region DR of the first semiconductor substrate 110 may be provided between the chip region CR and an outer sidewall of the first semiconductor substrate 110. The first semiconductor substrate 110 may include, for example, a semiconductor material such as silicon, germanium, or silicon-germanium. The first semiconductor substrate 110 may include a crystalline semiconductor material. The first semiconductor chip 100 may include first integrated circuits 115 as in FIG. 8. This will be described in detail with reference to FIG. 8.

An outer sidewall of the first semiconductor chip 100 may include a first outer sidewall 110a, a second outer sidewall 110b, a third outer sidewall, and a fourth outer sidewall. The second outer sidewall 110b may be adjacent to the first outer sidewall 110a. The third outer sidewall may be opposite to the first outer sidewall 110a and may be adjacent to the second outer sidewall 110b. The fourth outer sidewall may be opposite to the second outer sidewall 110b and may be adjacent to the first outer sidewall 110a and the third outer sidewall.

The first semiconductor chip 100 may include a first lower pad 150 which is disposed on a lower surface of the first semiconductor substrate 110. The first lower insulation layer 121 may be provided on the lower surface of the first semiconductor substrate 110 and may cover the first lower pad 150. The first lower insulation layer 121 may include a silicon-based insulating material. The silicon-based insulating material may include, for example, silicon oxide, silicon nitride, silicon oxynitride, and/or silicon carbide oxynitride. The first lower insulation layer 121 may include a plurality of stacked layers.

The first wiring pattern 123 may be provided in the first upper insulation layer 130. The first upper insulation layer 130 may include a plurality of layers. In an example embodiment, the first upper insulation layer 130 may include a first insulation layer 131 and a second insulation layer 132. However, this may be merely an example embodiment, and the first upper insulation layer 130 may be configured with three or more layers. The first wiring pattern 123, in more detail, may be provided in the first insulation layer 131. The first wiring pattern 123 may be electrically connected to at least one of the first integrated circuits 115 or the first through silicon via 170.

The first wiring pattern 123 may include a first aluminum wiring pattern 124 at an upper portion thereof. The first aluminum wiring pattern 124 may include aluminum and a material which differs from that of the first wiring pattern 123. A coefficient of thermal expansion of the first aluminum wiring pattern 124 may be greater than that of the first wiring pattern 123. An arbitrary element being electrically connected to a semiconductor chip may denote being electrically connected to at least one of integrated circuits and/or a through silicon via of the semiconductor chip. Herein, being electrically connected/contacting may include a direct connection/contact or an indirect connection/contact based on another conductive element.

The first lower pad 150 may be disposed on the lower surface of the first semiconductor chip 100. For example, the first lower pad 150 may be disposed on a lower surface of the first lower insulation layer 121. A vertical level of an upper surface of the first lower insulation layer 121 may be higher than or equal to a vertical level of an upper surface of the first lower pad 150. That is, the first lower pad 150 may be covered by the first lower insulation layer 121. In some example embodiments, the first lower insulation layer 121 may include an inorganic insulating material to which a compression stress is applied. In some example embodiments, the first lower insulation layer 121 may be formed to have a compression stress by a plasma-enhanced chemical vapor deposition (PECVD) process. For example, the first lower insulation layer 121 may include at least one of oxide or nitride. For example, the first lower insulation layer 121 may include at least one of silicon oxide or silicon nitride. A thickness of the first lower insulation layer 121 and/or a process condition of a PECVD process for forming the first lower insulation layer 121 may be adjusted for adjusting a compression stress of the first lower insulation layer 121.

The first lower pad 150 may be electrically connected to the first through silicon via 170. An upper surface of the first lower pad 150 may physically contact the first through silicon via 170. The first lower pad 150 may include, for example, aluminum or copper. The lower surface of the first semiconductor chip 100 may include a lower surface of the first lower pad 150 and a lower surface of the first lower insulation layer 121.

The lower bump 500 may be disposed on the lower surface of the first semiconductor chip 100. For example, the lower bump 500 may be disposed on the lower surface of the first lower pad 150 and may be electrically connected to the first lower pad 150. Therefore, the lower bump 500 may be electrically connected to the first semiconductor chip 100 and the second semiconductor chips 200 through the first lower pad 150. The lower pad 500 may include a conductive pillar 501 and a solder ball 503. The conductive pillar 501 may be provided between the first lower pad 150 and the solder ball 503 and may be electrically connected to the first lower pad 150 and the solder ball 503. The conductive pillar 501 may include a material which differs from that of the first lower pad 150 and the solder ball 503. For example, the conductive pillar 501 may include copper and/or a copper alloy. The solder ball 503 may include a solder material. The solder material may include tin (Sn), silver (Ag), zinc (Zn), and/or an alloy thereof.

The first semiconductor chip 100 may further include a guide ring 127. The guide ring 127 may be provided in the first upper insulation layer 130. In a two-dimensional perspective, the guide ring 127 may have a closed loop shape. In a two-dimensional perspective, the guide ring 127 may be provided between the first wiring pattern 123 and the dummy region DR of the first semiconductor substrate 110. The guide ring 127 may protect the first wiring pattern 123 or the first integrated circuits 115 from external pollution or an external stress. The guide ring 127 may include a metal material, but is not limited thereto.

The first through silicon via 170 may be provided in the first semiconductor substrate 110 and may pass through the first semiconductor substrate 110. The first through silicon via 170 may further pass through at least a portion of the first lower insulation layer 121. The first through silicon via 170 may be electrically connected to the first wiring pattern 123. The first through silicon via 170 may be electrically connected to the first lower pad 150 and/or connected to the first integrated circuits 115 through the first wiring pattern 123. The first through silicon via 170 may include, for example, metal such as copper, tungsten, titanium (Ti), titanium nitride (TiN), tantalum (Ta), and tantalum nitride (TaN).

The first upper insulation layer 130 may be disposed on the upper surface of the first semiconductor substrate 110. The upper surface of the first semiconductor substrate 110 may be opposite to the lower surface of the first semiconductor substrate 110. The upper surface of the first semiconductor substrate 110 may be a backside surface. The first through silicon via 170 may be further provided in the first upper insulation layer 130. The first upper insulation layer 130 may cover an upper sidewall of the first through silicon via 170.

The first upper insulation layer 130 may include the first insulation layer 131 and the second insulation layer 132. The first insulation layer 131 may cover the upper surface of the first semiconductor substrate 110, on the upper surface of the first semiconductor substrate 110. The first insulation layer 131 may be a multilayer or a single layer. The first insulation layer 131 may include a silicon-based insulating material. The first wiring pattern 123 may be provided in the first insulation layer 131.

The second insulation layer 132 may be disposed on the first insulation layer 131. The second insulation layer 132 may include a material which differs from that of the first insulation layer 131. For example, the second insulation layer 132 may include a silicon-based insulating material. As another example, the second insulation layer 132 may include an insulating polymer such as polyimide. An upper surface of the second insulation layer 132 may be the upper surface of the first semiconductor chip 100.

The first upper pad 160 may be disposed on the upper surface of the first semiconductor substrate 110. The first upper pad 160 may be provided on the first through silicon via 170 and may be electrically connected to the first through silicon via 170. Herein, a level of an element may denote a vertical level. The first upper pad 160 may be provided in the first upper insulation layer 130. For example, the first upper pad 160 may be provided in the second insulation layer 132. A side surface and a portion of a lower surface of the first upper pad 160 may be covered by the first upper insulation layer 130. An upper surface of the first upper pad 160 may not be covered by the first upper insulation layer 130. The first upper pad 160 may include metal such as copper. The upper surface of the first semiconductor chip 100 may include an upper surface of the first upper insulation layer 130 and an upper surface of the first upper pad 160.

A change in temperature applied to the first semiconductor chip 100 may cause the warpage of the first semiconductor chip 100. For example, while the first semiconductor chip 100 is being heated up to a second temperature from a first temperature, the first semiconductor chip 100 may be strained to be upward convex due to the rapid thermal expansion of the first aluminum wiring pattern 124 in the first wiring pattern 123. A volume of the first lower pad 150 may be greater than that of the first upper pad 160. Therefore, a load of the first semiconductor chip 100 may be applied to a lower portion thereof instead of an upper portion thereof. Accordingly, in a process of bonding the first semiconductor chip 100 and the second semiconductor chips 200, a warpage phenomenon caused by the heat of the first semiconductor chip 100 may be reduced.

A tensile stress generated in the first lower pad 150 may provide a compression stress opposite to a tensile stress generated in the first upper pad 160 and the first wiring pattern 123. The first lower pad 150 may be greater in volume than the first upper pad 160, and thus, a compression stress generated in the first lower pad 150 may be greater than a tensile stress generated in the first upper pad 160. Here, the compression stress may be a stress acting in a direction opposite to the tensile stress, and when the tensile stress denotes a stress having a positive value, the compression stress may denote a stress having a negative value.

A molding layer 400 may be provided on the upper surface of the first semiconductor chip 100 and may extend into a recessed portion 190. The molding layer 400 may cover the first upper insulation layer 130.

Unlike the illustration, the upper surface of the first semiconductor substrate 110 may be a frontside surface, and a backside surface of the first semiconductor substrate 110 may be a frontside surface. In this case, the first integrated circuits 115 and the first wiring pattern 123 may be disposed on the backside surface of the first semiconductor substrate 110.

Hereinafter, elements of the second semiconductor chip 200 will be described.

The second semiconductor chips 200 may be provided on the first semiconductor chip 100 as in FIG. 2. For example, the second semiconductor chips 200 may be disposed in the chip region CR of the first semiconductor substrate 110. Each of the second semiconductor chips 200 may include a second semiconductor substrate 210, a second integrated circuit, a second lower insulation layer 221, a second lower pad 250, a second wiring pattern 223, a second through silicon via 270, a second upper pad 260, and a second upper insulation layer 230. Unless separately described, materials and an electrical connection relationship of the second semiconductor substrate 210, the second integrated circuit, the second lower insulation layer 221, the second lower pad 250, the second wiring pattern 223, and the second through silicon via 270 may be substantially the same as materials and an electrical connection relationship of the first semiconductor substrate 110, the first integrated circuits 115, the first lower insulation layer 121, the first lower pad 150, the first wiring pattern 123, and the first through silicon via 170.

The second semiconductor substrate 210 may be a second substrate. The second integrated circuits may be provided on a lower surface of the second semiconductor substrate 210. The lower surface of the second semiconductor substrate 210 may be a frontside surface. The second integrated circuits may be circuits which differ from the kind of first integrated circuits (115 of FIG. 8). The second integrated circuits each may be a memory circuit. The second semiconductor substrate 210 may include a semiconductor material.

The second lower insulation layer 221 may be provided on the lower surface of the second semiconductor substrate 210 and may cover the second integrated circuit. The second lower insulation layer 221 may be a multilayer. The second lower insulation layer 221 may include a silicon-based insulating material. For example, the second lower insulation layer 221 may include an inorganic insulating material to which a compression stress is applied. In some example embodiments, the second lower insulation layer 221 may be formed to have a compression stress by a PECVD process. For example, the second lower insulation layer 221 may include at least one of oxide or nitride. For example, the second lower insulation layer 221 may include at least one of silicon oxide or silicon nitride. A thickness of the second lower insulation layer 221 and/or a process condition of a PECVD process for forming the first lower insulation layer 121 may be adjusted for adjusting a compression stress of the second lower insulation layer 221.

The second lower pad 250 may be disposed on the lower surface of the second semiconductor chip 200. For example, the second lower pad 250 may be disposed on a lower surface of the second lower insulation layer 221. The lower surface of the second semiconductor chip 200 may include a lower surface of the second lower pad 250 and a lower surface of the second lower insulation layer 221. The second lower pad 250 may include, for example, copper.

The second through silicon via 270 may be provided in the second semiconductor substrate 210 and may pass through the second semiconductor substrate 210. The second through silicon via 270 may be electrically connected to the second wiring pattern 223. The second through silicon via 270 may include metal. Therefore, the second lower pad 250 and the second wiring pattern 223 may be electrically connected to each other through the second through silicon via 270.

The second upper insulation layer 230 may be disposed on the upper surface of the second semiconductor substrate 210. The upper surface of the second semiconductor substrate 210 may be a backside surface. The second upper insulation layer 230 may be a multilayer. For example, the second upper insulation layer 230 may include a silicon-based insulating material. The second wiring pattern 223 may be provided in the second upper insulation layer 230. The second wiring pattern 223 may include metal. The second wiring pattern 223 may include a second aluminum wiring pattern 224 at an upper portion thereof. The second aluminum wiring pattern 224 may include aluminum and a material which differs from that of the second wiring pattern 223. The second upper pad 260 may be electrically connected to the second integrated circuit and/or the second through silicon via 270 through the second wiring pattern 223. The second upper pad 260 may be provided in the second upper insulation layer 230. An upper surface of the second upper pad 260 may not be covered by the second upper insulation layer 230. The second upper pad 260 may include, for example, metal such as copper.

A change in temperature applied to the second semiconductor chips 200 may cause the warpage of the second semiconductor chips 200. For example, while the second semiconductor chips 200 are being heated up to the second temperature from the first temperature, the second semiconductor chips 200 may be strained to be upward convex due to the rapid thermal expansion of a metal wiring pattern of the second wiring pattern 223. A volume of the second lower pad 250 may be greater than that of the second upper pad 260. Accordingly, in a process of bonding each of the second semiconductor chips 200, a warpage phenomenon caused by the heat of each of the second semiconductor chips 200 may be reduced.

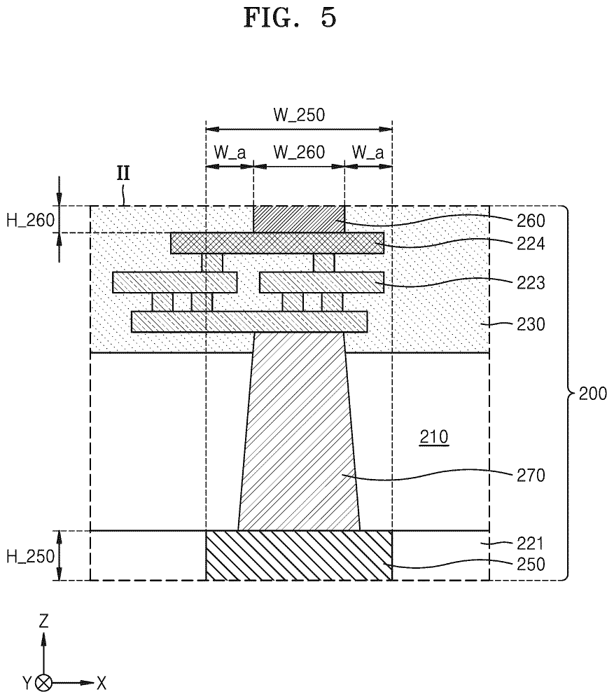

A tensile stress generated in the second lower pad 250 may provide a compression stress opposite to a tensile stress generated in the second upper pad 260 and the second wiring pattern 223 (as well as the second aluminum wiring pattern 224). The second lower pad 250 may be greater in volume than the second upper pad 260, and thus, a compression stress generated in the second lower pad 250 may be greater than a tensile stress generated in the second upper pad 260. Here, the compression stress may be a stress acting in a direction opposite to the tensile stress, and when the tensile stress denotes a stress having a positive value, the compression stress may denote a stress having a negative value. In some example embodiments, the second wiring pattern 223 (as well as the second aluminum wiring pattern 224) and the second lower pads 250 each including metal may have a tensile stress, and a compression stress provided by the second upper pad 260 may offset or decrease a tensile stress occurring in the second wiring pattern 223 and the second aluminum wiring pattern 224. Standard of each of the second lower pad 250 and the second upper pad 260 will be described below in detail with reference to FIGS. 5 to 7.

An uppermost second semiconductor chip 200 may include the second semiconductor substrate 210, the second integrated circuit, the second lower insulation layer 221, and the second lower pad 250 and may not include the second through silicon via 270, the second upper pad 260, the second wiring pattern 223, and the second upper insulation layer 230. A thickness of the second semiconductor substrate 210 of the uppermost second semiconductor chip 200 may be greater than that of the second semiconductor substrate 210 of each of the other second semiconductor chips 200. The uppermost second semiconductor chip 200 may be referred to as a third semiconductor chip.

A molding layer 400 may be disposed on the upper surface of the first semiconductor chip 100 and may cover sidewalls of the second semiconductor chips 200. An upper surface of the molding layer 400 may expose the upper surface of the uppermost second semiconductor chip 200. For example, the upper surface of the molding layer 400 may be provided at the same or substantially similar level as the upper surface of the uppermost second semiconductor chip 200. In some example embodiments, the molding layer 400 may further cover the upper surface of the uppermost second semiconductor chip 200. The molding layer 400 may include an insulating polymer such as an epoxy molding compound (EMC).

A lowermost second semiconductor chip 200 may be directly bonded to the first semiconductor chip 100. The first semiconductor chip 100 and the second semiconductor chips 200 each included in the semiconductor package 10 may be directly bonded to each other. Direct bonding may be formed by a hybrid bonding process. The second lower pad 250 of the lowermost second semiconductor chip 200 may be directly bonded to the first upper pad 160. For example, the second lower pad 250 of the lowermost second semiconductor chip 200 may be directly disposed on the first upper pad 160 and may directly and physically contact the first upper pad 160. The second lower pad 250 of the lowermost second semiconductor chip 200 may include the same metal (for example, copper) as that of the first upper pad 160. An interface between the first upper pad 160 and the second lower pad 250 of the lowermost second semiconductor chip 200 may not be differentiated, but is not limited thereto. An area of the first upper pad 160 may differ from that of the second lower pad 250 physically contacting the first upper pad 160, in a horizontal direction. Accordingly, a sidewall of the first upper pad 160 may not match a sidewall of the second lower pad 250 physically contacting the first upper pad 160.

The second lower insulation layer 221 of the lowermost second semiconductor chip 200 may be directly bonded to the first upper insulation layer 130. For example, a chemical bond may be formed between the first upper insulation layer 130 and the second lower insulation layer 221 of the lowermost second semiconductor chip 200. In an example embodiment, a bump and an insulation film surrounding the bump, which are used in a thermal compression bonding (TCB) process and are disposed between the first semiconductor chip 100 and the second semiconductor chips 200, may be omitted. A thickness of a semiconductor package in a vertical direction may be relatively more thinned by direct bonding. The second lower insulation layer 221 of the lowermost second semiconductor chip 200 may be solidly bonded to the first upper insulation layer 130 by direct bonding. The second lower insulation layer 221 of the lowermost second semiconductor chip 200 may include the same insulating material as that of the first upper insulation layer 130, but is not limited thereto. For example, an interface between the first upper insulation layer 130 and the second lower insulation layer 221 of the lowermost second semiconductor chip 200 may not be differentiated.

The second semiconductor chip chips 200 may be directly bonded to each other. For example, the second upper pad 260 and the second lower pad 250 facing each other may directly contact and be directly bonded to each other. An interface between the second upper pad 260 and the second lower pad 250 directly bonded to each other may not be differentiated. The interface between the second upper pad 260 and the second lower pad 250 directly bonded to each other may be a virtual interface. The second lower pad 250 may include the same metal (for example, copper) as that of the second upper pad 260 directly bonded thereto. An area of the second upper pad 260 may differ from that of the second lower pad 250 physically contacting the second upper pad 260, in a horizontal direction. Accordingly, a sidewall of the second upper pad 260 may not match a sidewall of the second lower pad 250 physically contacting the second upper pad 260.

The second lower insulation layer 221 may be directly bonded to the second upper insulation layer 230 facing the second lower insulation layer 221. For example, the second lower insulation layer 221 may directly contact the second upper insulation layer 230 facing the second lower insulation layer 221. A chemical bond may be formed between the second lower insulation layer 221 and the second upper insulation layer 230 directly bonded to each other. Accordingly, a solid bond may be formed between the second lower insulation layer 221 and the second upper insulation layer 230 directly bonded to each other. The second lower insulation layer 221 may include the same material as that of the second upper insulation layer 230 directly bonded thereto, but is not limited thereto. For example, an interface between the second lower insulation layer 221 and the second upper insulation layer 230 directly bonded to each other may not be differentiated.

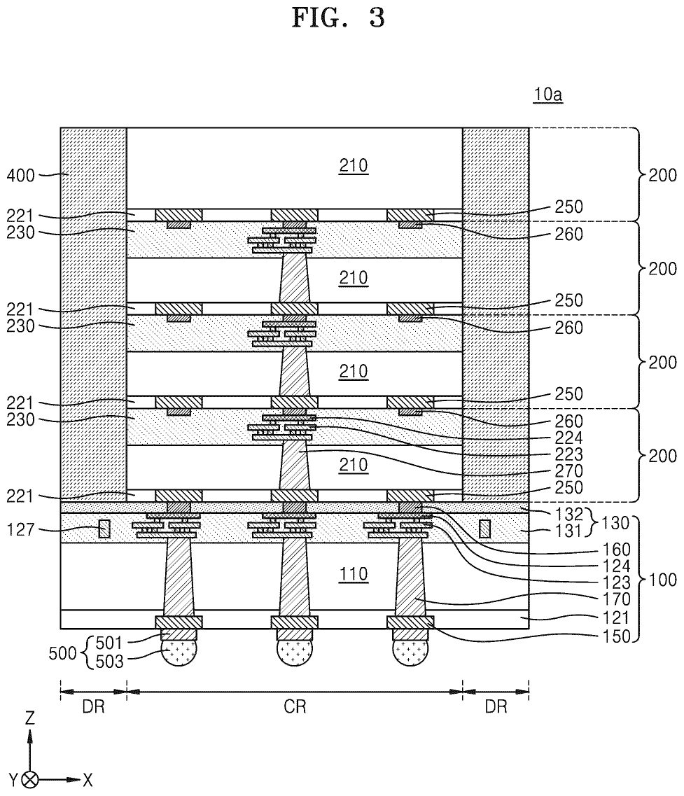

FIG. 3 is a cross-sectional view taken along line I-I′ of FIG. 1, according to another example embodiment.

In describing FIG. 3 with reference to FIG. 2, differences from FIG. 2 may be mainly described. Each of second semiconductor chips 200 included in a semiconductor package 10a may include a second semiconductor substrate 210 and a second through silicon via 270 passing through the second semiconductor substrate 210. The second through silicon via 270 may be disposed between a second lower pad 250 and a second upper pad 260. The second through silicon via 270 may be disposed to contact an upper surface of the second lower pad 250. However, the second through silicon via 270 may not be disposed on the upper surface of the second lower pad 250. That is, each of the second semiconductor chips 200 may include a plurality of second lower pads 250, and the second through silicon via 270 may be disposed on an upper surface of at least one of the plurality of second lower pads 250. Therefore, the second through silicon via 270 may not be disposed on an upper surface of some of the second lower pads 250. The second lower pad 250 and the second upper pad 260 of FIG. 3 may correspond to the second lower pad 250 and the second upper pad 260 of FIG. 2, respectively. Accordingly, regardless of the presence or absence of corresponding second through silicon vias 270, second lower pads 250 may be further disposed under each of the second semiconductor chips 200, and thus, a load may be further applied to a lower portion, thereby decreasing a warpage phenomenon in bonding based on a second wiring pattern 223 included in each of the second semiconductor chips 200. Moreover, the second wiring pattern 223 may not be disposed in a region where the second through silicon via 270 is not disposed. In an example embodiment, the second through silicon via 270 may be connected to the second wiring pattern 223, and the second wiring pattern 223 may be connected and electrically connected to the second upper pad 260. Each of the second semiconductor chips 200 may include a plurality of second upper pads 260, and the second through silicon via 270 may be disposed under at least one of the plurality of second upper pads 260. Therefore, the second through silicon via 270 may not be disposed under some of the second upper pads 260. In a case where the second through silicon via 270 is not disposed under the second upper pad 260, the second wiring pattern 223 also may not be disposed under the second upper pad 260.

In FIG. 3, each of the second semiconductor chips 200 may include three second upper pads 260 and second lower pads 250. In an example embodiment, the second through silicon via 270 may be disposed between only a middle second upper pad 260 and a middle second lower pad 250 among the three second upper pads 260 and second lower pads 250. The second through silicon via 270 may be between the middle second upper pad 260 and the middle second lower pad 250 among the three second upper pads 260 and second lower pads 250, and moreover, may be disposed between a left second upper pad 260 and a left second lower pad 250 or between a right second upper pad 260 and a right second lower pad 250. In an example embodiment, the second wiring pattern 223 may be disposed between only the middle second upper pad 260 and the middle second lower pad 250 among the three second upper pads 260 and second lower pads 250. The second wiring pattern 223 may be between the middle second upper pad 260 and the middle second lower pad 250 among the three second upper pads 260 and second lower pads 250, and moreover, may be disposed between the left second upper pad 260 and the left second lower pad 250 or between the right second upper pad 260 and the right second lower pad 250.

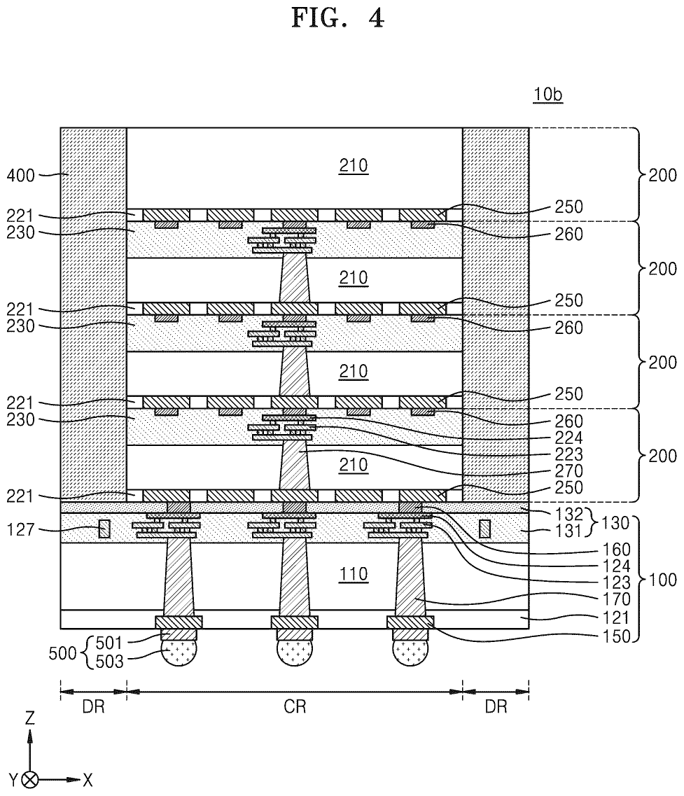

FIG. 4 is a cross-sectional view taken along line I-I′ of FIG. 1, according to another example embodiment.

In describing FIG. 4 with reference to FIGS. 2 and 3, differences from FIGS. 2 and 3 may be mainly described.

In FIG. 3, each of the second semiconductor chips 200 included in the semiconductor package 10a may include the three second upper pads 260 and second lower pads 250. In an example embodiment, in FIG. 4, each of second semiconductor chips 200 included in a semiconductor package 10b is illustrated as including five second upper pads 260 and five second lower pads 250, but is not limited thereto and may include more second upper pads 260 and second lower pads 250. All of the second upper pad 260 and the second lower pad 250 may overlap a horizontal area of the second semiconductor chips 200. Intervals between the second upper pads 260 and intervals between the second lower pads 250 may differ. As the number of second upper pads 260 and the number of second lower pads 250 increase, a difference between a compression stress and a tensile stress caused by the second lower pad 250 may increase, and warpage occurring in a hybrid bonding process may be more reduced.

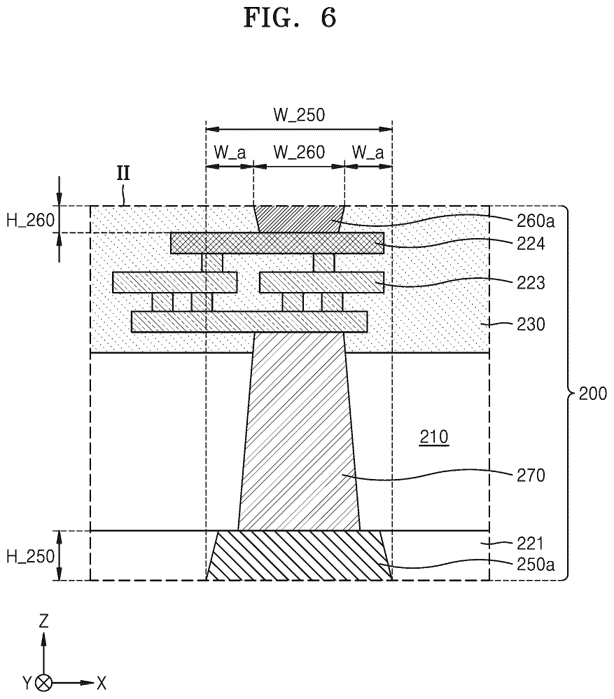

FIG. 5 is an enlarged view of a region II of FIG. 2, according to an example embodiment. FIG. 6 is an enlarged view of a region II of FIG. 2, according to another example embodiment.

FIG. 5 is referred to together with FIG. 2. A level of an upper surface of a second lower pad 250 may be the same as that of an upper surface of a second lower insulation layer 221.

A second wiring pattern 223 may include a second aluminum wiring pattern 224 at an upper portion thereof. A thickness of the second aluminum wiring pattern 224 may be equal to a thickness of each element of second wiring patterns 223. The second aluminum wiring pattern 224 may include aluminum and a material which differs from that of the second wiring pattern 223. The second aluminum wiring pattern 224 disposed at an uppermost portion among the second wiring patterns 223 may be greater in value than the other second wiring pattern 223 which differs in coefficient of thermal expansion (CTE). In an example embodiment, a coefficient of thermal expansion of the second aluminum wiring pattern 224 may be about 23.6 cc/° C., and a coefficient of thermal expansion of a portion, including copper, of the second wiring pattern 223 may be about 16.5 cc/° C.

A volume of the second lower pad 250 may be greater than that of a second upper pad 260. When the second lower pad 250 and the second upper pad 260 include the same material (e.g., copper), a weight of the second lower pad 250 may be greater than that of the second upper pad 260.

A thickness H_250 of the second lower pad 250 in a vertical direction (a Z direction) may be greater than a thickness H_260 of the second upper pad 260 in the vertical direction (the Z direction). An area W_250 of the second lower pad 250 in a horizontal direction may be about two times greater than an area W_260 of the second upper pad 260 in the horizontal direction. An area where the second lower pad 250 overlaps the second upper pad 260 may be about half of the area W_250 of the second lower pad 250. In some example embodiments as illustrated in FIG. 6, when an area of a portion which does not overlap is assumed to be W_a, W_a (e.g., a sum of W_a on the right side of W_250 and W_a on the left side of W_250) may be about half of W_250. In FIG. 6, with respect to only one horizontal direction, W_250, W_260, and W_a may have a shape equal to one width, but each of W_250, W_260, and W_a may correspond to an area which is equal to the multiplication of a length in a first horizontal direction (an X direction) and a length in a second horizontal direction (a Y direction) perpendicular to the first horizontal direction (the X direction). Referring to FIG. 6, each of a second lower pad 250a and a second upper pad 260a may have a tapered shape where a width in a horizontal direction decreases progressively toward the second semiconductor substrate 210. In FIG. 6, a thickness H_250 of the second lower pad 250a in the vertical direction (the Z direction) may be greater than a thickness H_260 of the second upper pad 260a in the vertical direction (the Z direction). An area W_250 of the second lower pad 250a in a horizontal direction may be about two times greater an area W_260 of the second upper pad 260a in the horizontal direction. Here, an area may denote a largest value among areas of each second lower pad 250a and second upper pad 260a.

Example embodiments may be variously combined. For example, among the example embodiments of FIGS. 2 to 4, the example embodiment of FIG. 5, and the example embodiment of FIG. 6, two embodiments may be combined with each other. For example, the semiconductor package 10a of FIG. 3 or the semiconductor package 10b of FIG. 4 may include the second upper pad 260 or the second lower pad 250, which is tapered as illustrated in the example embodiment of FIG. 6.

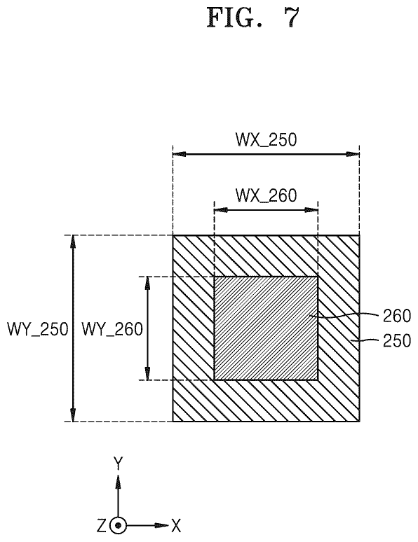

FIG. 7 is a plan view illustrating a second upper pad and a second lower pad each included in a semiconductor package according to an example embodiment.

A length WX_250 of a second lower pad 250 in a first horizontal direction (an X direction) and a length WY_250 of the second lower pad 250 in a second horizontal direction (a Y direction) perpendicular to the first horizontal direction (the X direction) may be greater than a length WX_260 of a second upper pad 260 in the first horizontal direction (the X direction) and a length WY_260 of the second upper pad 260 in the second horizontal direction (the Y direction), respectively. An area of the second lower pad 250 in a horizontal direction may be calculated as in the following Equation 1. An area of the second upper pad 260 in the horizontal direction may be calculated as in the following Equation 2.

area of second lower pad=(WX_250)*(WY_250) [Equation 1]

area of second upper pad=(WX_260)*(WY_260) [Equation 2]

In FIG. 7, it is illustrated that a center of the second upper pad 260 matches a center of the second lower pad 250, and it is illustrated that the second upper pad 260 is disposed at the center of the second lower pad 250, but the center of the second upper pad 260 may not match the center of the second lower pad 250. In an example embodiment, the second upper pad 260 in the horizontal direction may not overlap and entirety of an area of the second lower pad 250 in the horizontal direction.

FIG. 8 is an enlarged view of a region III of FIG. 2, according to an example embodiment.

First integrated circuits 115 may be disposed in an upper portion of a chip region CR of a first semiconductor substrate 110. A lower surface of the first semiconductor substrate 110 may be a frontside surface. The first integrated circuits 115 may not be provided in a dummy region DR of the first semiconductor substrate 110. The first integrated circuits 115 may include transistors. The first integrated circuits 115 may include logic circuits. A first insulation layer 131 may be provided in an upper portion of the first semiconductor substrate 110 and may cover the first integrated circuits 115.

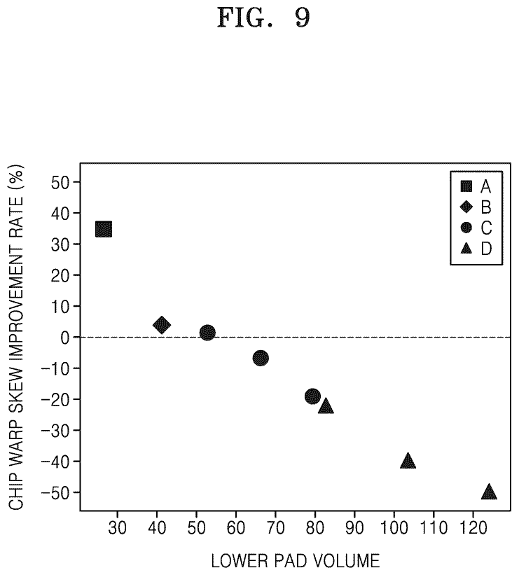

FIG. 9 is a graph showing a warpage skew improvement rate of a semiconductor chip with respect to a lower pad volume depending on each case.

Referring to FIG. 9, A may denote a case of the related art. B, C, and D may denote cases of some example embodiments of the inventive concepts. B may denote a case where an area of a second lower pad increases compared to a second upper pad. C may denote a case where a thickness of the second lower pad increases compared to the second upper pad. D may denote a case where both of an area and a thickness of the second lower pad increase compared to the second upper pad.

A Y axis may represent a warpage skew improvement rate of a semiconductor chip and may represent a ratio of a value which decreases a tensile stress, based on a compression stress described above. In A, it may be seen that an improvement ratio is about mid-30s %, and a tensile stress increase by about 30% to more deteriorate skew caused by warpage. In B, it may be seen that a tensile stress is not largely affected. In C, it may be seen that a tensile stress is not largely affected when a volume of the second lower pad is about 50%, but as the volume of the second lower pad increases, skew caused by warpage is improved to reduce a tensile stress up to 20%. In D, it may be seen that the volume of the second lower pad is about 80% and large, and a tensile stress decreases up to 50%, and thus, skew caused by warpage is improved.

Therefore, a depth and a width of a lower pad may be greater than a depth and a width of an upper pad, and thus, an asymmetric structure may be formed. Accordingly, it may be seen that a difference between a volume of an upper metal and a volume of a lower metal caused by a wiring pattern of semiconductor chips may compensate for the stress caused by a wiring patten vertically therebetween, and thus a warpage difference caused by the expansion and contraction of the wiring pattern may be reduced. Accordingly, a defect occurring in a bonding process may decrease.

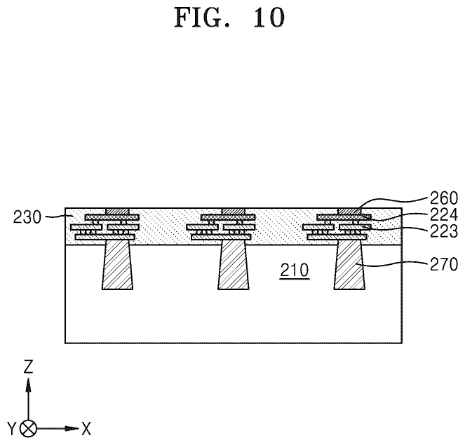

FIGS. 10 to 13 are diagrams for describing a manufacturing process of a semiconductor package according to an example embodiment.

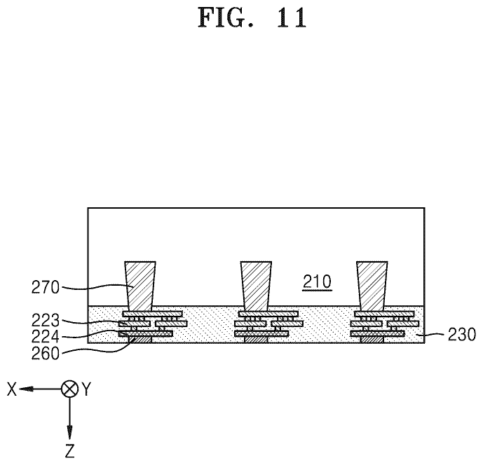

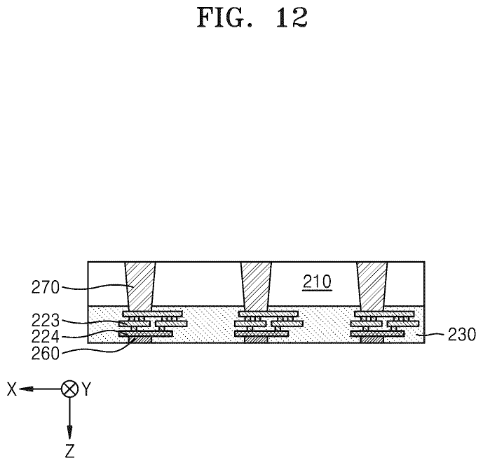

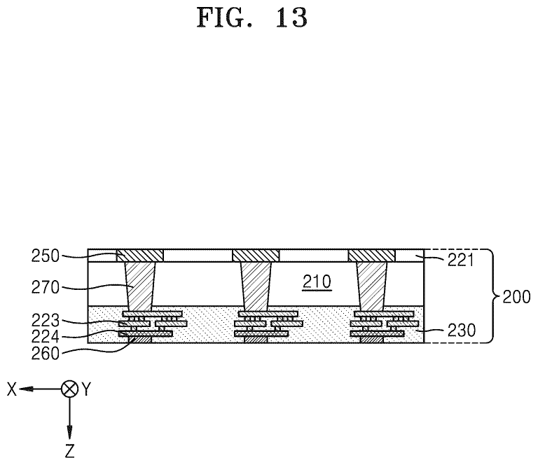

Referring to FIG. 10, a second through silicon via 270 may be formed on a second semiconductor substrate 210. A second wiring pattern 223 may be formed on an upper surface of the second through silicon via 270. Subsequently, a second upper insulation layer 230 may be formed, and a second upper pad 260 may be formed in the second upper insulation layer 230. In forming the second upper pad 260, a photo process and an etching process may be performed together. Referring to FIG. 11, the second semiconductor substrate 210 may be reversed. Referring to FIG. 12, a vertical level may be lowered through a chemical mechanical polishing (CMP) process of grinding the second semiconductor substrate 210. A CMP process may be performed until a vertical level of the second semiconductor substrate 210 becomes equal to a vertical level of the upper surface of the second through silicon via 270. In an example embodiment, the upper surface of the second through silicon via 270 may be exposed. Referring to FIG. 13, a second lower insulation layer 221 may be formed on an exposed upper surface of the second through silicon via 270. A second lower pad 250 may be formed in the second lower insulation layer 221. The second lower pad 250 may cover the upper surface of the second through silicon via 270. In forming the second lower pad 250, a photo process and an etching process may be performed together. In a reversed case as in FIGS. 11 and 12, an upper surface of FIG. 13 may correspond to a lower surface of FIG. 2.

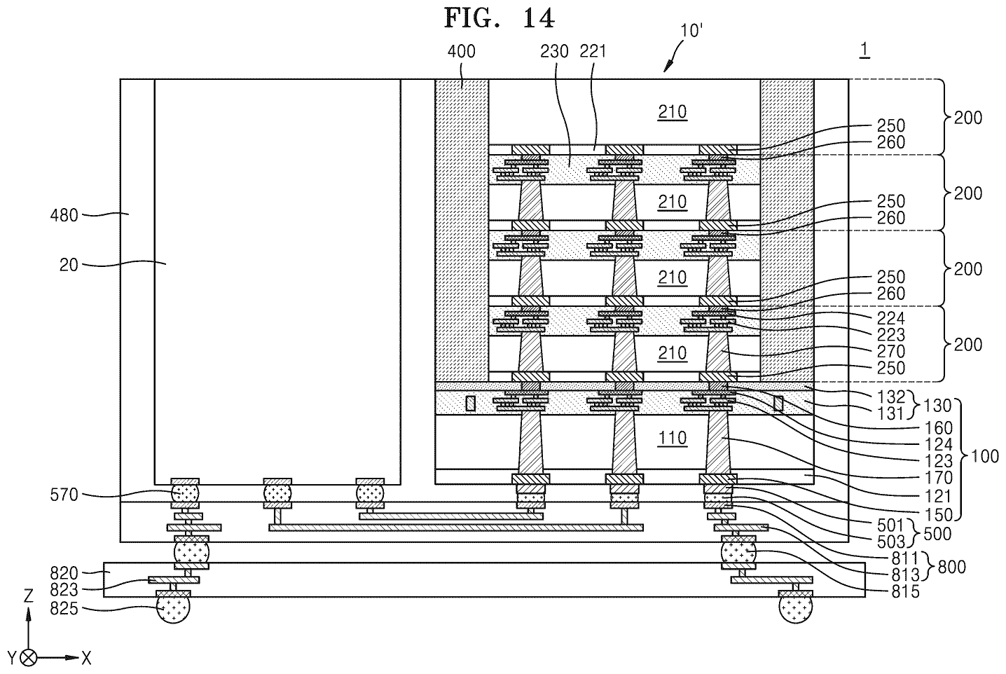

FIG. 14 is a cross-sectional view illustrating a semiconductor package 1 according to example embodiments.

Referring to FIG. 14, the semiconductor package 1 may include solder balls 825, a package substrate 820, interposer solder balls 815, an interposer substrate 800, a semiconductor device 20, and a chip stack package 10′.

For example, a printed circuit board may be used as the package substrate 820. The package substrate 820 may include substrate wirings 823. The substrate wirings 823 may be provided in the package substrate 820. Being electrically connected to the package substrate 820 may denote being electrically connected to at least one of the substrate wirings 823. The substrate wirings 823 may include metal such as copper, aluminum, tungsten, and/or titanium.

The solder balls 825 may be provided on a lower surface of the package substrate 820 and may be electrically connected to the substrate wirings 823. External electrical signals may be transferred to the solder balls 825. The solder balls 825 may include a solder material.

The interposer substrate 800 may be provided on the package substrate 820. The interposer substrate 800 may include upper interposer pads 811 and interposer wirings 813. The upper interposer pads 811 may be disposed on an upper surface of the interposer substrate 800. The upper interposer pads 811 may include metal. The interposer wirings 813 may be provided in the interposer substrate 800 and may be electrically connected to the upper interposer pads 811. Being electrically connected to the interposer substrate 800 may denote being electrically connected to at least one of the interposer wirings 813. The interposer wirings 813 may include metal such as copper, aluminum, tungsten, and/or titanium.

The interposer solder balls 815 may be disposed between the package substrate 820 and the interposer substrate 800 and may be electrically connected to the package substrate 820 and the interposer substrate 800. A pitch of the interposer solder balls 815 may be less than a pitch of the solder balls 825. The interposer solder balls 815 may include a solder material.

The chip stack package 10′ may be disposed on the upper surface of the interposer substrate 810. The semiconductor package described above in the example embodiment of FIG. 2 may be used as the chip stack package 10′. For example, the chip stack package 10′ may include a first semiconductor chip 100, second semiconductor chip 200, a molding layer 430, and lower bumps 500. On the other hand, the semiconductor package 10a of FIG. 3 or the semiconductor package 10b of FIG. 4 may be used as the chip stack package 10′.

The lower bumps 500 may be provided on the upper interposer pads 811 and may be electrically connected to the upper interposer pads 811. For example, the lower bumps 500 may be bonded to upper surfaces of corresponding upper interposer pads 811. A pitch of the lower bumps 500 may be less than a pitch of the interposer solder balls 815.

The semiconductor device 20 may be provided on the interposer substrate 810 and may be laterally apart from the chip stack package 10′. The semiconductor device 20 may include a graphics processing unit (GPU) or a central processing unit (CPU). The semiconductor device 20 may be a semiconductor chip which differs from the kind of first semiconductor chip 100 and second semiconductor chips 200. The semiconductor device 20 may perform a function which differs from functions of the first semiconductor chip 100 and the second semiconductor chips 200. The semiconductor device 20 may include integrated circuits and chip pads. The integrated circuits may be provided in the semiconductor device 20. The chip pads may be provided on a lower surface of the semiconductor device 20 and may be electrically connected to the integrated circuits of the semiconductor device 20.

Conductive bumps 570 may be disposed between the interposer substrate 800 and the semiconductor device 20. For example, the conductive bumps 570 may be electrically connected to chip pads of the semiconductor device 20 and corresponding upper interposer pads 811. The conductive bumps 570 may include a solder material. A pitch of the conductive bumps 570 may be less than a pitch of the interposer solder balls 815. The semiconductor device 20 may be electrically connected to the chip stack package 10′ through the interposer substrate 810. The semiconductor device 20 may be electrically connected to the package substrate 820 and the solder balls 825 through the interposer substrate 810.

A molding pattern 480 may be disposed on an upper surface of the interposer substrate 810 and may cover sidewalls of the chip stack package 10′ and sidewalls of the semiconductor device 20. For example, the molding pattern 480 may cover outer sidewalls of the first semiconductor chip 100 and outer sidewalls of the molding layer 400. The molding pattern 480 may physically contact outer sidewalls of the first semiconductor substrate 110. The molding pattern 480 may include a polymer such as an EMC. The molding pattern 480 may have an insulating characteristic.

Unlike the illustration, the semiconductor package 1 may include two or more chip stack packages 10′. In this case, the semiconductor device 20 may be disposed between the chip stack packages 10′.

Hereinabove, some example embodiments have been described in the drawings and the specification. The example embodiments have been described by using the terms described herein to describe the inventive concepts and not to limit a meaning or limiting the scope of the inventive concepts defined in the following claims. Therefore, it may be understood by those of ordinary skill in the art that various modifications and other equivalent embodiments may be implemented from the example embodiments described above. Accordingly, the spirit and scope of the inventive concepts may be defined based on the spirit and scope of the following claims.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a first semiconductor chip including a device region and a dummy region surrounding the device region in a two-dimensional perspective;
second semiconductor chips on an upper surface of the device region of the first semiconductor chip; and
a molding layer on the first semiconductor chip, the molding layer covering the second semiconductor chips,
wherein each of the second semiconductor chips comprises
a second semiconductor substrate,
a second lower pad on a lower surface of the second semiconductor substrate, and
a second upper pad on an upper surface of the second semiconductor substrate, and
a volume of the second lower pad is greater than a volume of the second upper pad.

2. The semiconductor package of claim 1, wherein a thickness of the second lower pad in a vertical direction is greater than a thickness of the second upper pad in the vertical direction.

3. The semiconductor package of claim 1, wherein a length of the second lower pad in a first horizontal direction and a length of the second lower pad in a second horizontal direction perpendicular to the first horizontal direction are greater than a length of the second upper pad in the first horizontal direction and a length of the second upper pad in the second horizontal direction, respectively.

4. The semiconductor package of claim 1, wherein an area of the second lower pad in a horizontal direction is two times an area of the second upper pad in the horizontal direction.

5. The semiconductor package of claim 1, wherein, when viewed from above, an area where the second upper pad overlaps the second lower pad is half of an area of the second lower pad.

6. The semiconductor package of claim 1, wherein each of the second lower pad and the second upper pad has a tapered shape where a width in a horizontal direction decreases progressively toward the second semiconductor substrate.

7. The semiconductor package of claim 1, wherein
the first semiconductor chip comprises:
a first semiconductor substrate;
a first lower pad on a lower surface of the first semiconductor substrate; and
a first upper pad in an upper portion of the first semiconductor substrate, and
a volume of the first lower pad is greater than a volume of the first upper pad.

8. The semiconductor package of claim 7, wherein
the first semiconductor chip is in contact with a lowermost second semiconductor chip in a hybrid bonding manner, and
the first upper pad directly and physically contacts the second lower pad.

9. The semiconductor package of claim 1, wherein
the second semiconductor chips are in contact with each other in a hybrid bonding manner, and
the second lower pad of one of the second semiconductor chips directly and physically contacts the second upper pad of another one of the second semiconductor chips that is closest to the second lower pad of the one of the second semiconductor chips.

10. The semiconductor package of claim 1, further comprising:
an interposer substrate;
bumps between the interposer substrate and the first semiconductor chip; and
a semiconductor device on an upper surface of the interposer substrate, the semiconductor device being laterally apart from the first semiconductor chip,
wherein the first semiconductor chip is electrically connected to the semiconductor device through the interposer substrate.

11. A semiconductor package comprising:
a first semiconductor chip;
second semiconductor chips on an upper surface of the first semiconductor chip; and
a molding layer on the first semiconductor chip, the molding layer covering the second semiconductor chips,
wherein the first semiconductor chip comprises
a first semiconductor substrate,
a first upper insulation layer on an upper surface of the first semiconductor substrate, the first upper insulation layer including a first insulation layer and a second insulation layer,
a first upper pad in the second insulation layer, and
a first lower pad on a lower surface of the first semiconductor substrate,
each of the second semiconductor chips comprises
a second semiconductor substrate,
a second upper insulation layer on an upper surface of the second semiconductor substrate,
a second lower insulation layer on a lower surface of the second semiconductor substrate,
a second upper pad in the second upper insulation layer, and
a second lower pad in the second lower insulation layer,
a volume of the first lower pad is greater than a volume of the first upper pad, and
a volume of the second lower pad is greater than a volume of the second upper pad.

12. The semiconductor package of claim 11, wherein
the first semiconductor chip further comprises:
a first through silicon via passing through the first semiconductor substrate; and
a first wiring pattern in the first insulation layer, the first wiring pattern electrically connected to the first through silicon via, and
the first insulation layer is under the second insulation layer.

13. The semiconductor package of claim 11, wherein each of the second semiconductor chips further comprises:
a second through silicon via passing through the second semiconductor substrate; and
a second wiring pattern on a lower surface of the second upper pad, the second wiring pattern electrically connected to the second through silicon via.

14. The semiconductor package of claim 11, wherein
a thickness of the second lower pad in a vertical direction is greater than a thickness of the second upper pad in the vertical direction, and
a length of the second lower pad in a first horizontal direction and a length of the second lower pad in a second horizontal direction perpendicular to the first horizontal direction are greater than a length of the second upper pad in the first horizontal direction and a length of the second upper pad in the second horizontal direction, respectively.

15. The semiconductor package of claim 11, wherein, when viewed from above,
an area of the second lower pad is two times an area of the second upper pad, and
an area where the second upper pad overlaps the second lower pad is half of an area of the second lower pad.

16. The semiconductor package of claim 11, wherein
the first semiconductor chip is in contact with a lowermost second semiconductor chip in a hybrid bonding manner,
the first upper pad directly and physically contacts the second lower pad,
the second semiconductor chips are in contact with each other in a hybrid bonding manner, and
the second lower pad of one of the second semiconductor chips directly and physically contacts the second upper pad of another one of the second semiconductor chips that is closest to the second lower pad of the one of the second semiconductor chips.

17. The semiconductor package of claim 11, wherein a thickness of each of the second upper pad and the second lower pad is 1 μm to 10 μm.

18. The semiconductor package of claim 11, wherein a width of each of the second upper pad and the second lower pad is 1 μm to 20 μm.

19. A semiconductor package comprising:
a first semiconductor chip including
a first semiconductor substrate,
a first upper insulation layer on an upper surface of the first semiconductor substrate, the first upper insulation layer including a first insulation layer and a second insulation layer,
a first through silicon via passing through the first semiconductor substrate,
a first wiring pattern in the first insulation layer, the first wiring pattern electrically connected to the first through silicon via,
a first upper pad in the second insulation layer, the first upper pad electrically connected to the first wiring pattern, and
a first lower pad on a lower surface of the first semiconductor substrate;
second semiconductor chips on an upper surface of the first semiconductor chip, each of the second semiconductor chips including
a second semiconductor substrate,
a second upper insulation layer on an upper surface of the second semiconductor substrate,
a second lower insulation layer on a lower surface of the second semiconductor substrate,
a second upper pad in the second upper insulation layer, and
a second lower pad in the second lower insulation layer;
a molding layer on the first semiconductor chip, the molding layer covering sidewalls of the second semiconductor chips; and
a lower bump on a lower surface of the first semiconductor chip, the lower bump electrically connected to the first lower pad,
wherein a thickness of the second lower pad in a vertical direction is greater than a thickness of the second upper pad in the vertical direction,
a length of the second lower pad in a first horizontal direction and a length of the second lower pad in a second horizontal direction perpendicular to the first horizontal direction are greater than a length of the second upper pad in the first horizontal direction and a length of the second upper pad in the second horizontal direction, respectively, and
when viewed from above,
an area of the second lower pad is two times an area of the second upper pad, and
an area where the second upper pad overlaps the second lower pad is half of an area of the second lower pad.

20. The semiconductor package of claim 19, wherein each of the second semiconductor chips further comprises:
a second through silicon via on an upper surface of at least one of the second lower pads, the second through silicon via passing through the second semiconductor substrate; and
a second wiring pattern on a lower surface of the second upper pad, the second wiring pattern electrically connected to the second through silicon via.
